(19) United States
(12) Patent Application Publication
(10) Pub. No.: US 2025/0183109 A1
(43) Pub. Date: Jun. 5, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chien-Wei HSIEH, Taichung City (TW); Ko-Wei CHANG, Taichung City (TW); Wen-Yang LI, Taichung City (TW); Chih-Hsien CHIU, Taichung City (TW); Chia-Yang CHEN, Taichung City (TW); Chin-Wen LAI, Taichung City (TW)

(21) Appl. No.: 18/822,738

(22) Filed: Sep. 3, 2024

(30) Foreign Application Priority Data
Dec. 4, 2023 (TW) 112147079

(51) Int. Cl. H01L 23/31; H01L 23/495

(52) U.S. Cl. CPC H01L 23/3171; H01L 23/4952

(57) ABSTRACT

The present disclosure discloses an electronic package and a manufacturing method thereof. An electronic component is disposed on a substrate, an encapsulation layer covers the electronic component, and a frame that is not in contact with the substrate is embedded in the encapsulation layer, thereby preventing the electronic package from warping by the frame resisting thermal stress.

### CROSS-REFERENCE TO RELATED APPLICATIONS

The present application is based upon and claims the right of priority to TW patent application No. 112147079, filed Dec. 4, 2023, the disclosure of which is hereby incorporated by reference herein in its entirety for all purposes.

### BACKGROUND

### 1. Technical Field

The present disclosure relates to a semiconductor device, and more particularly, to an anti-warp electronic package and a manufacturing method thereof.

### 2. Description of Related Art

A flip-chip ball grid array (FCBGA) semiconductor package is a package structure that enables an active surface of at least one chip to be electrically connected to one surface of a substrate via a plurality of solder bumps, and a plurality of solder balls serving as input/output (I/O) terminals to be planted on the other surface of the substrate. This package structure can greatly reduce the size while eliminating the traditional wire design, and can reduce impedance and improve electrical properties to avoid signal degradation during transmission. Therefore, it has indeed become the mainstream packaging technology for the next generation of chips and electronic components.

With the development of semiconductor technology, the function of chip integration and the increase in the number of I/Os, a sufficiently large I/O spacing is required in order to ensure the stability of subsequent assembly. Therefore, a ratio of the chip size to package size also increases. This is because the coefficient of thermal expansion (CTE) of the chip is too different from the CTE of the substrate, and the molding compound (M/C) is formed on most of the substrate surface, causing the warpage of the package to become difficult to control.

In addition, in response to the rapid development of flip-chip chip scale packages (FCCSP), a chip with fine line spacing needs to use coreless embedded trace substrates (ETS) to bring out signals. Therefore, the method to control warpage is usually to adjust the thickness of M/C or select different types of encapsulation compounds for optimization. However, as packages become larger and larger, the effect of increasing the thickness of the encapsulation compound or selecting a different type of encapsulation compound becomes less and less effective. In particular, the former method may increase the height of the package, making the overall volume larger and unable to meet the needs of end products that are light, thin and short.

Please refer to FIG. 1, although the industry has subsequently developed a structure that combines an annular metal frame 12 on a substrate 10 to control warpage (as shown in FIG. 1 below), the metal frame 12 usually becomes larger and thicker. Although this improvement in warpage is obvious, a metal frame 12 that is too large may reduce the placement of other electronic components. Therefore, the size of the substrate must be increased, which increases the cost. In addition, the overall volume would be larger, making it impossible to meet the requirements of the end product being light, thin and short. Therefore, how to solve the above problems has become a difficult problem that the industry needs to overcome urgently.

### SUMMARY

In view of the various deficiencies of the prior art, the present disclosure provides an electronic package, which comprises: a substrate; an electronic component disposed on the substrate and electrically connected to the substrate; an encapsulation layer formed on the substrate to cover the electronic component; and a frame embedded in the encapsulation layer and located on a periphery of the substrate and free from being in contact with the substrate.

The present disclosure further provides a method of manufacturing an electronic package, which comprises: providing a support member having an opening; disposing a substrate in the opening of the support member; disposing an electronic component on the substrate; disposing a frame in the opening of the support member, wherein the frame is located on the periphery of the substrate and free from being in contact with the substrate; and forming an encapsulation layer on the support member so that the encapsulation layer covers the substrate, the electronic component and the frame.

In the aforementioned electronic package and the manufacturing method thereof, the method further comprises providing a carrier structure to dispose the support member on the carrier structure, and removing the carrier structure after forming the encapsulation layer.

In the aforementioned electronic package and the manufacturing method thereof, the frame is annular and surrounds the periphery of the substrate.

In the aforementioned electronic package and the manufacturing method thereof, the frame is partially exposed from the encapsulation layer. For example, the encapsulation layer has a first surface and a second surface opposing the first surface, and the frame has a bottom surface that is flush with the second surface of the encapsulation layer; or the frame has a top surface that is flush with the first surface of the encapsulation layer; or the frame is exposed from a side surface adjacent to the first surface and the second surface; or a height of the frame is greater than a height of the electronic component, so that the frame is exposed from the first surface of the encapsulation layer, and the electronic component is embedded in the encapsulation layer.

In the aforementioned electronic package and the manufacturing method thereof, the electronic component is partially exposed from the encapsulation layer.

In the aforementioned electronic package and the manufacturing method thereof, the method further comprises forming a shielding layer on the encapsulation layer. In addition, a plurality of conductive components can be further formed on the frame, so as to be ground connection with an external device via the plurality of conductive components.

In the aforementioned electronic package and the manufacturing method thereof, the method further comprises disposing a plurality of conductive components on the substrate, wherein the plurality of conductive components are exposes from the encapsulation layer.

In the aforementioned electronic package and the manufacturing method thereof, the method further comprises disposing a plurality of conductive components on the frame, wherein the plurality of conductive components are exposed from the encapsulation layer.

As can be seen from the above, in the electronic package and its manufacturing method of the present disclosure, the frame resists thermal stress and prevents the encapsulation layer from warping during thermal cycles. Furthermore, by arranging the frame outside the substrate, it is convenient to arrange other electronic component s around the electronic component without increasing the size of the substrate, thereby reducing the manufacturing cost.

### BRIEF DESCRIPTION OF THE DRAWINGS

FIG. 1 is a schematic cross-sectional view of a conventional semiconductor package.

FIG. 2A to FIG. 2D-1 are schematic cross-sectional views illustrating a manufacturing method of an electronic package according to a first embodiment of the present disclosure.

FIG. 2D-2 is a partial bottom view of FIG. 2D-1.

FIG. 3 is a schematic cross-sectional view of an electronic package according to a second embodiment of the present disclosure.

FIG. 4-1 is a schematic cross-sectional view of an electronic package according to a third embodiment of the present disclosure.

FIG. 4-2 is a schematic cross-sectional view of other embodiments of FIG. 4-1.

FIG. 5-1 is a schematic cross-sectional view of an electronic package according to a fourth embodiment of the present disclosure.

FIG. 5-2 and FIG. 5-3 are schematic cross-sectional views of other embodiments of FIG. 5-1.

FIG. 6A and FIG. 6B are cross-sectional and bottom views of an electronic package according to a fifth embodiment of the present disclosure.

### DETAILED DESCRIPTIONS

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

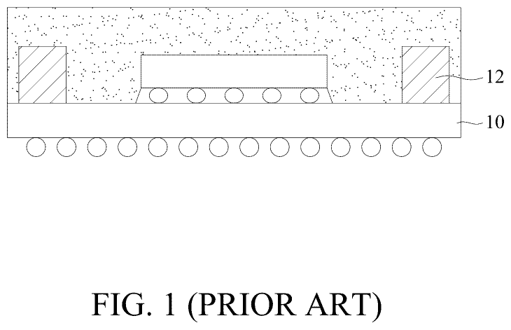

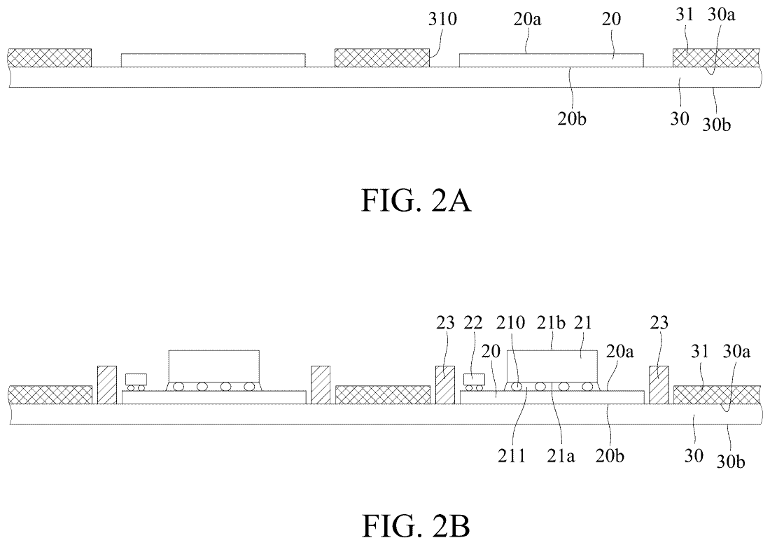

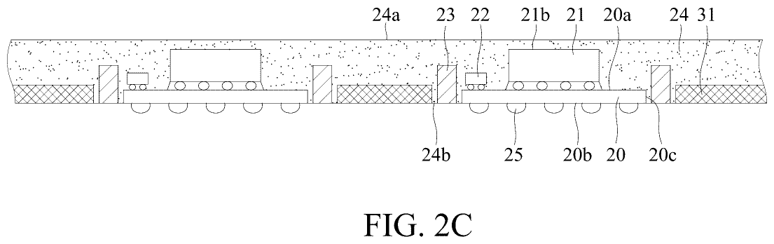

FIG. 2A to FIG. 2D-1 are schematic cross-sectional views illustrating a manufacturing method of an electronic package 2 according to the present disclosure.

As shown in FIG. 2A, a carrier structure 30 having a first side 30a and a second side 30b opposing the first side 30a is provided. A support member 31 having a plurality of openings 310 is disposed on the first side 30a of the carrier structure 30, and a substrate 20 is disposed in the openings 310 of the support member 31. In one embodiment, it is shown that two substrates 20 are respectively disposed in two adjacent ones of the openings 310, but the present disclosure is not limited to as such.

The carrier structure 30 may be a temporary carrier board, which may include, for example, a carrier board composed of an organic polymer sheet or a copper foil substrate, but the present disclosure is not limited to as such.

The substrate 20 may be a package substrate having a core layer and a circuit portion or a coreless circuit structure. In one embodiment, the substrate 20 includes at least one dielectric layer and a circuit layer bonded to the dielectric layer. The substrate 20 has a first side 20a and a second side 20b opposing the first side 20a, wherein the second side 20b of the substrate 20 is bonded to the first side 30a of the carrier structure 30.

It should be understood that the substrate 20 can also be other carrying units for carrying chips, such as a lead frame, a wafer, a silicon interposer, or other types of board having metal routing, and the like, and the present disclosure is not limited to as such.

As shown in FIG. 2B, at least one electronic component 21 is disposed on the first side 20a of the substrate 20 via a plurality of conductive bumps 210, and a coating layer such as underfill 211 is formed to fill between the first side 20a of the substrate 20 and the electronic component 21 to cover the conductive bumps 210. In addition, at least one electronic accessory 22 can be disposed around the electronic component 21.

The electronic component 21 is an active component, a passive component, or a combination thereof, and the active component is, for example, a semiconductor chip, and the passive component is, for example, a resistor, a capacitor, and an inductor. In one embodiment, the electronic component 21 is a semiconductor chip, which has an active surface 21a and an inactive surface 21b opposing the active surface 21a, and the active surface 21a has a plurality of electrode pads (not shown), so that the electrode pads are bonded and electrically connected to the circuit layer of the substrate 20 via a plurality of conductive bumps 210 made of solder material in a flip-chip manner. In addition, in one embodiment, the electronic accessory 22 is a passive component, which can also be disposed in a space where the electronic component 21 is not arranged on the first side 20a of the substrate 20 via conductive bumps.

In other embodiments, the electronic component 21 can also be electrically connected to the circuit layer of the substrate 20 via a plurality of bonding wires in a wire bonding manner (not shown); alternatively, the electronic component 21 can be directly electrically connected to the circuit layer of the substrate 20. It should be understood that there are many ways to electrically connect the electronic components 21 and the electronic accessories 22 to the substrate 20, and the required type and quantity of electronic components 21 and electronic accessories 22 can be connected to the substrate 20, and the present disclosure is not limited to as such.

Furthermore, a frame 23 is provided in the opening 310 of the support member 31, wherein the frame 23 is located on a periphery of the substrate 20 and does not contact the substrate 20.

The frame 23 is a metal frame such as copper or a semiconductor frame such as silicon or glass. In one embodiment, the frame 23 is annular and surrounds the substrate 20.

As shown in FIG. 2C, an encapsulation layer 24 is formed on the first side 30a of the carrier structure 30, so that the encapsulation layer 24 covers the support member 31, the substrates 20, the electronic components 21, the electronic accessories 22 and the frames 23, and then the carrier structure 30 is removed to expose the second side 20b of each of the substrates 20.

In addition, after removing the carrier structure 30, a plurality of conductive components 25 can be disposed on the second side 20b of the substrate 20, such as metal pillars of copper pillars, metal bumps covered with insulating blocks, solder balls, solder balls with Cu core balls or other conductive structures.

The encapsulation layer 24 has a first surface 24a and a second surface 24b opposing the first surface 24a. In one embodiment, the first surface 24a of the encapsulation layer 24 is higher than the inactive surface 21b of the electronic component 21 to completely cover the electronic component 21, and the second surface 24b of the encapsulation layer 24 is flush with the second side 20b of the substrate 20.

In this embodiment, the encapsulating layer 24 is an insulating material, such as polyimide (PI), dry film, encapsulating colloid such as epoxy resin or other molding compounds. For example, the encapsulation layer 24 may be formed on the carrier structure 30 by lamination or compression molding.

As shown in FIG. 2D-1, a cutting operation (a singulation process) is performed on each of the substrates 20, so that the encapsulation layer 24 defines a side surface 24c adjacent to the first surface 24a and the second surface 24b to form the electronic package 2 of the present disclosure, wherein a bottom surface of the frame 23 is flush with the second surface 24b of the encapsulation layer 24.

In one embodiment, a cutting path is set to not cut the frame 23, so that the frame 23 is exposed from the second surface 24b of the encapsulation layer 24 but not exposed from the side surface 24c.

In addition, in one embodiment, as shown in the bottom view of FIG. 2D-2, the frame 23 can be formed in an annular shape, and continuously surrounds the periphery of the side surface 20c of the substrate 20 without contacting the substrate 20. It should be understood that in other embodiments, the frame 23 can also be distributed in a discontinuous manner (not shown) around the side surface 20c of the electronic component 21.

Based on the above, the manufacturing method of the present disclosure mainly relies on the design of the frame 23 to reduce warpage during thermal cycles and to conduct heat from electronic component s outwards. Furthermore, since the frame 23 does not contact the substrate 20, it is convenient to arrange other electronic components or electronic accessories around the electronic component 21 without increasing the size of the substrate 20, thereby reducing the manufacturing cost. In addition, the aforementioned manufacturing method does not require the addition of new development processes and materials or the purchase of machines. Therefore, existing technical problems in the industry can be solved using existing materials, old processes and machines, without incurring a large amount of additional costs.

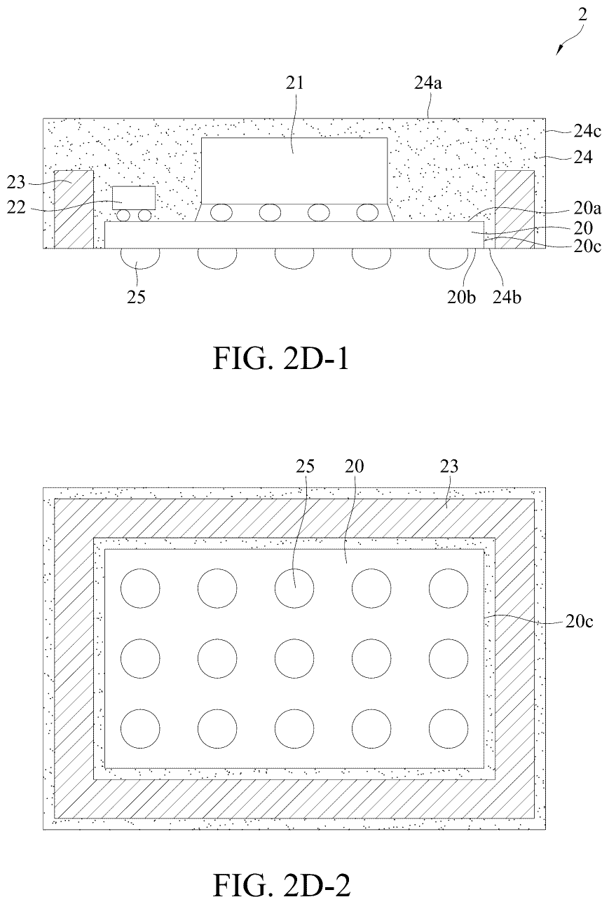

Please refer to FIG. 3, which is a schematic cross-sectional view showing an electronic package 3 according to a second embodiment of the present disclosure. In the electronic package 3, the cutting path can pass through the frame 33, so that the frame 33 is not only exposed from the second surface 24b of the encapsulation layer 24, but also exposed from the side surface 24c of the encapsulation layer 24.

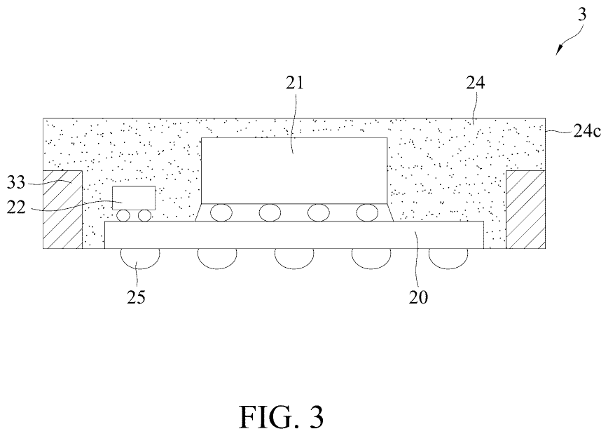

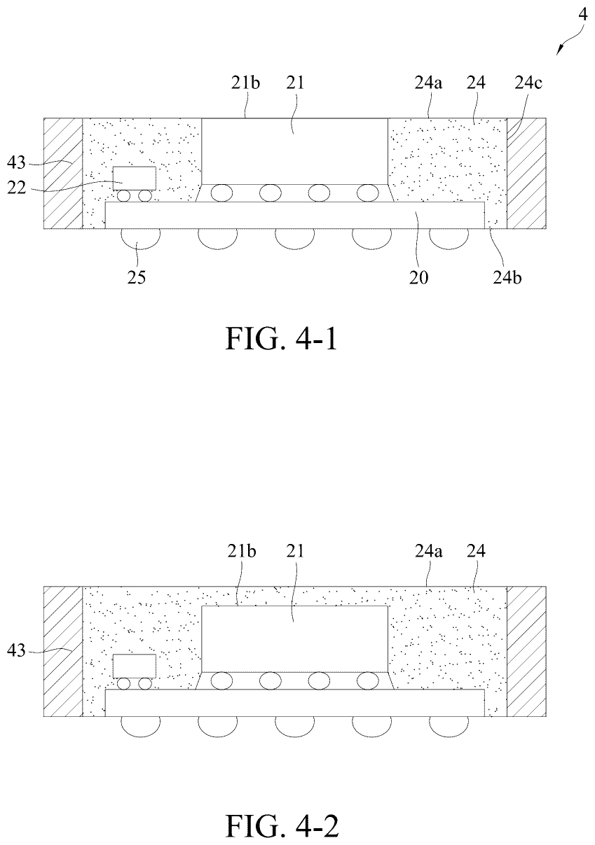

Please refer to FIG. 4-1, which is a schematic cross-sectional view showing an electronic package 4 according to a third embodiment of the present disclosure. In the electronic package 4, the inactive surface 21b of the electronic component 21 is exposed from the first surface 24a of the encapsulation layer 24. Specifically, part of the material of the encapsulation layer 24 (even part of the material of the inactive surface 21b of the electronic component 21) can be removed via a leveling process (such as grinding), wherein the first surface 24a of the encapsulation layer 24 is flush with the inactive surface 21b of the electronic component 21 and the top surface of the frame 43, so that the inactive surface 21b of the electronic component 21 is exposed from the first surface 24a of the encapsulation layer 24. A frame 43 can even be exposed from the first surface 24a, the second surface 24b and the side surface 24c of the encapsulation layer 24 at the same time, thereby improving the heat dissipation performance of the electronic component 21.

In another embodiment, as shown in FIG. 4-2, the height of the frame 43 is greater than the height of the electronic component 21, wherein the frame 43 is exposed from the first surface 24a of the encapsulation layer 24, but the electronic component 21 is still embedded in the encapsulation layer 24 without being exposed from the first surface 24a of the encapsulation layer 24.

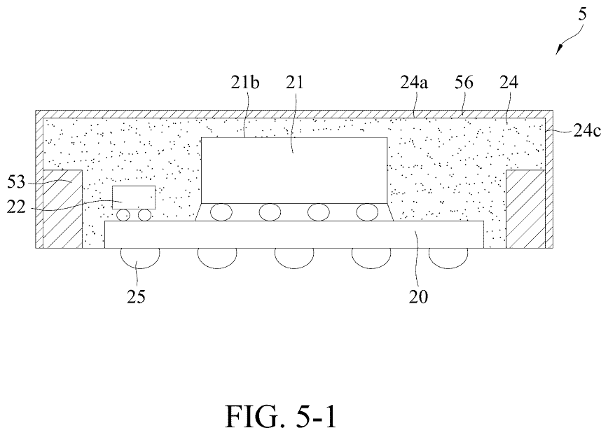

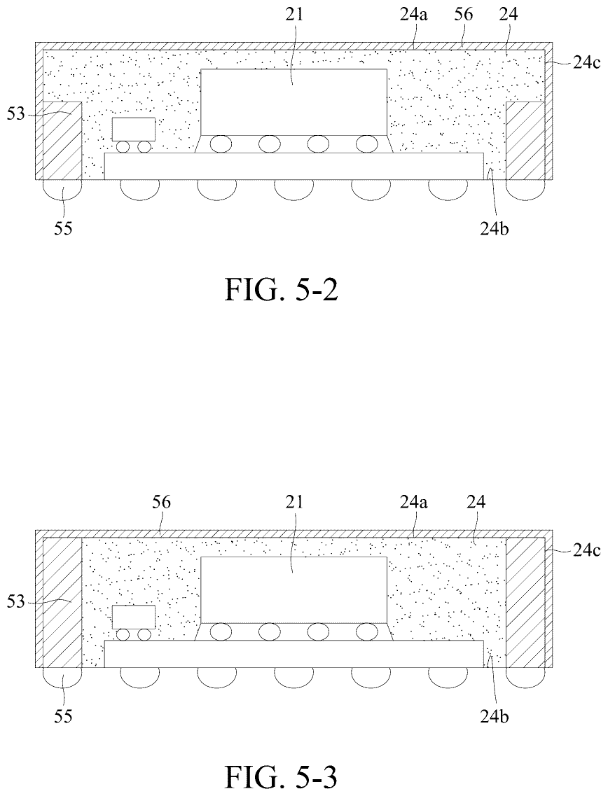

Please refer to FIG. 5-1, which is a schematic cross-sectional view showing an electronic package 5 according to a fourth embodiment of the present disclosure. In the electronic package 5, mainly after the singulation process, a frame 53 is exposed from the side surface 24c of the packaging layer 24, and a shielding layer 56 is formed on the side surface 24c and the first surface 24a of the encapsulation layer 24, so that the shielding layer 56 contacts the frame 53 at the side surface 24c of the encapsulation layer 24. In addition, in other embodiments, the shielding layer 56 may also contact the frame 53 at the first surface 24a or the second surface 24b of the encapsulation layer 24, or may not contact the frame 53. It should be understood that the shielding layer 56 can be in contact with or not in contact with the electronic component 21 as required, and can also be in contact with or not in contact with the frame 53 as required, and the present disclosure is not particularly limited to as such. In one embodiment, the design of the shielding layer 56 is mainly used to prevent the electronic component 21 from being affected by electromagnetic interference (EMI), and at the same time, the heat dissipation performance of the electronic component 21 can be improved.

In another implementation, as shown in FIG. 5-2 and FIG. 5-3, the frame 53 can optionally be exposed from the side surface 24c of the encapsulation layer 24 or simultaneously be exposed from the first surface 24a and the side surface 24c of the encapsulation layer 24, wherein a shielding layer 56 is formed on the first surface 24a and the side surface 24c of the encapsulation layer 24 so that the shielding layer 56 contacts the frame 53. In addition, a plurality of conductive components 55 can be implanted on the frame 53, which is exposed from the second surface 24b of the encapsulation layer 24, for subsequent ground connection with external devices via the plurality of conductive components 55. In addition, the conductive components 55 are connected to the frame 53 to make the entire electronic package more stable when connected to the external devices.

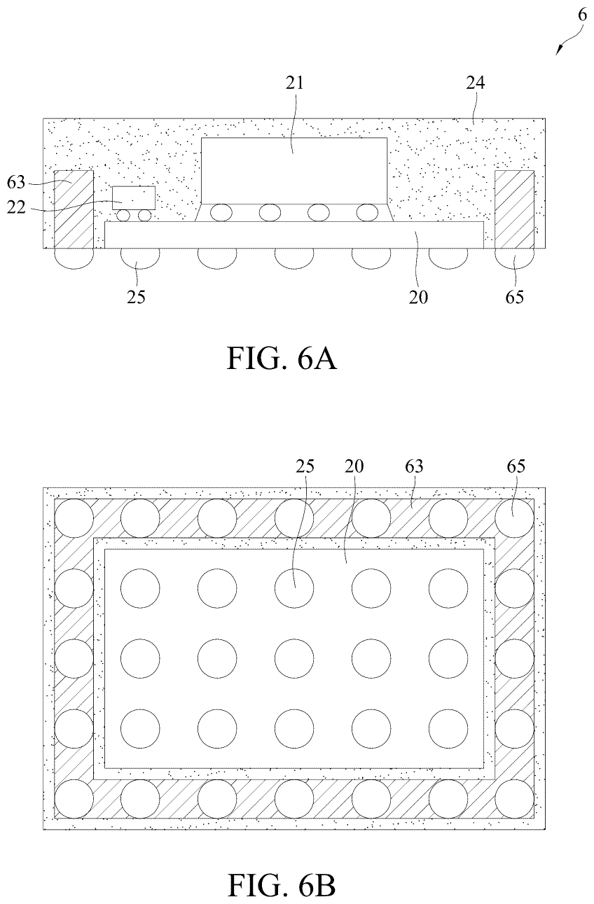

Please refer to FIG. 6A and FIG. 6B, which are schematic cross-sectional and bottom views showing an electronic package 6 according to of a fifth embodiment of the present disclosure. In one embodiment, a conductive component 65 is mainly planted on a frame 63, which is exposed from the second surface 24b of the encapsulation layer 24, so that the problem of insufficient support in the peripheral area of the electronic package 6 when the electronic package 6 is too large and the area of the substrate 20 is too small can be avoided when the electronic package 6 is subsequently connected to an external device. At the same time, when the conductive component 65 installed on the frame 63 is connected to an external device, the heat generated by the electronic package 6 can be transferred to the external device for heat dissipation. In addition, the conductive component 65 is connected to the frame 63 to make the entire electronic package 6 more stable when it is connected to the external device.

The present disclosure also provides an electronic package 2, 3, 4, 5, 6, which includes: a substrate 20, an electronic component 21, an encapsulation layer 24 and a frame 23, 33, 43, 53, 63.

The electronic component 21 is disposed on the substrate 20 and is electrically connected to the substrate 20. In addition, an electronic accessory 22 can be disposed on the substrate 20.

The encapsulation layer 24 is formed on the substrate 20 to cover the electronic component 21, wherein the encapsulation layer 24 has a first surface 24a, a second surface 24b opposing the first surface 24a and a side surface 24c adjacent to the first surface 24a and the second surface 24b, and the second surface 24b of the encapsulation layer 24 is flush with the second side 20b of the substrate 20.

The frame 23, 33, 53, 63 is embedded in the encapsulation layer 24, and is located on a periphery of the substrate 20 and does not contact the substrate 20.

In one embodiment, the frame 23 is annular and surrounds the periphery of the substrate 20.

In one embodiment, the frame 23, 33, 53, 63 is partially exposed from the encapsulation layer 24.

In one embodiment, the electronic component 21 is partially exposed from the encapsulation layer 24.

In one embodiment, the electronic package 5 further includes a shielding layer 56 formed on the encapsulation layer 24.

In one embodiment, the conductive component 65 can be planted on the frame 63 being exposed the second surface 24b of the encapsulation layer 24.

To sum up, the electronic package and its manufacturing method of the present disclosure are designed to resist the thermal stress in the electronic package via the design of the frame, so that the encapsulation layer can be prevented from warping during thermal cycles. Furthermore, since the frame does not contact the substrate, it is convenient to mount an electronic component on the substrate without increasing the size of the substrate, thereby reducing manufacturing costs.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a substrate;
an electronic component disposed on the substrate and electrically connected to the substrate;
an encapsulation layer formed on the substrate to cover the electronic component; and
a frame embedded in the encapsulation layer and located on a periphery of the substrate and free of being in contact with the substrate.

2. The electronic package of claim 1, wherein the frame is annular and surrounds the periphery of the substrate.

3. The electronic package of claim 1, wherein the frame is partially exposed from the encapsulation layer.

4. The electronic package of claim 1, wherein the encapsulation layer has a first surface and a second surface opposing the first surface, and the frame has a bottom surface that is flush with the second surface of the encapsulation layer.

5. The electronic package of claim 1, wherein the encapsulation layer has a first surface and a second surface opposing the first surface, and the frame has a top surface that is flush with the first surface of the encapsulation layer.

6. The electronic package of claim 1, wherein the encapsulation layer has a first surface, a second surface opposing the first surface and a side surface adjacent to the first surface and the second surface, and the frame is exposed from the side surface.

7. The electronic package of claim 1, wherein the encapsulation layer has a first surface and a second surface opposing the first surface, and a height of the frame is greater than a height of the electronic component, so that the frame is exposed from the first surface of the encapsulation layer, and the electronic component is embedded in the encapsulation layer.

8. The electronic package of claim 1, wherein the electronic component is partially exposed from the encapsulation layer.

9. The electronic package of claim 1, further comprising a shielding layer formed on the encapsulation layer.

10. The electronic package of claim 9, further comprising a plurality of conductive components formed on the frame.

11. The electronic package of claim 5, further comprising a shielding layer formed on the encapsulation layer.

12. The electronic package of claim 11, further comprising a plurality of conductive components formed on the frame.

13. The electronic package of claim 6, further comprising a shielding layer formed on the encapsulation layer.

14. The electronic package of claim 13, further comprising a plurality of conductive components formed on the frame.

15. The electronic package of claim 1, further comprising a plurality of conductive components disposed on the substrate and exposed from the encapsulation layer.

16. The electronic package of claim 1, further comprising a plurality of conductive components, and the conductive components are disposed on the frame and exposed from the encapsulation layer.

17. A method of manufacturing an electronic package, comprising:
providing a support member having an opening;
disposing a substrate in the opening of the support member;
disposing an electronic component on the substrate;
disposing a frame in the opening of the support member, wherein the frame is located on a periphery of the substrate and free from being in contact with the substrate; and
forming an encapsulation layer on the support member so that the encapsulation layer covers the substrate, the electronic component and the frame.

18. The method of claim 17, further comprising providing a carrier structure to dispose the support member on the carrier structure, and removing the carrier structure after forming the encapsulation layer.

19. The method of claim 17, wherein the frame is annular and surrounds the periphery of the substrate.

20. The method of claim 17, wherein the frame is partially exposed from the encapsulation layer.

21. The method of claim 17, wherein the encapsulation layer has a first surface and a second surface opposing the first surface, and the frame has a bottom surface that is flush with the second surface of the encapsulation layer.

22. The method of claim 17, wherein the encapsulation layer has a first surface and a second surface opposing the first surface, and the frame has a top surface that is flush with the first surface of the encapsulation layer.

23. The method of claim 17, wherein the encapsulation layer has a first surface, a second surface opposing the first surface and a side surface adjacent to the first surface and the second surface, and the frame is exposed from the side surface.

24. The method of claim 17, wherein the encapsulation layer has a first surface and a second surface opposing the first surface, and a height of the frame is greater than a height of the electronic component, so that the frame is exposed from the first surface of the encapsulation layer, and the electronic component is embedded in the encapsulation layer.

25. The method of claim 17, wherein the electronic component is partially exposed from the encapsulation layer.

26. The method of claim 17, further comprising forming a shielding layer on the encapsulation layer.

27. The method of claim 26, further comprising forming a plurality of conductive components on the frame.

28. The method of claim 22, further comprising forming a shielding layer on the encapsulation layer.

29. The method of claim 28, further comprising forming a plurality of conductive components on the frame.

30. The method of claim 23, further comprising forming a shielding layer on the encapsulation layer.

31. The method of claim 30, further comprising forming a plurality of conductive components on the frame.

32. The method of claim 17, further comprising disposing a plurality of conductive components on the substrate, wherein the plurality of conductive components are exposed from the encapsulation layer.

33. The method of claim 17, further comprising disposing a plurality of conductive components on the frame, wherein the plurality of conductive components are exposes from the encapsulation layer.
